(19) United States
(12) Patent Application Publication
(10) Pub. No.: US 2013/0119416 A1
(43) Pub. Date: May 16, 2013

(54) LIGHT-EMITTING DIODE AND DISPLAY APPARATUS USING SAME

(71) Applicant: PANASONIC CORPORATION, Osaka (JP)

(72) Inventors: Kazuhiro YONEDA, Osaka (JP); Keiko KURATA, Hyogo (JP); Noriyuki MATSUSUE, Osaka (JP)

(73) Assignee: PANASONIC CORPORATION, Osaka (JP)

(21) Appl. No.: 13/734,228

(22) Filed: Jan. 4, 2013

Related U.S. Application Data
(63) Continuation of application No. PCT/JP2011/004063, filed on Jul. 15, 2011.

(30) Foreign Application Priority Data
Jul. 22, 2010 (JP) 2010-164646

(51) Int. Cl. H01L 33/08; H01L 33/60

(52) U.S. Cl. CPC H01L 33/08; H01L 33/60
USPC 257/89; 257/98

(57) ABSTRACT

To provide a light-emitting diode enabling improvements to color purity as well as to luminous efficiency, a light-emitting diode comprises a reflective electrode and a transparent electrode having functional layers therebetween, the functional layers being a transparent conductive layer, a hole injection layer, and a hole transport layer, and further comprises a light-emitting layer emitting blue light and having an electron transport layer layered thereon, such that a total optical layer thickness of the functional layers sandwiched between the reflective electrode and the light-emitting layer is in a range of 455.4 nm to 475.8 nm, inclusive.

### CROSS REFERENCE TO RELATED APPLICATION

This is a continuation application of PCT Application No. PCT/JP2011/004063 filed Jul. 15, 2011, designating the United States of America, the disclosure of which, including the specification, drawings and claims, is incorporated herein by reference in its entirety.

### TECHNICAL FIELD

The present disclosure relates to a light-emitting diode employing the phenomenon of organic material electroluminescence, and to display device using the light-emitting diode.

### DESCRIPTION OF THE RELATED ART

Due to progress in the field of organic electroluminescence and organic electroluminescence elements (hereinafter, organic EL elements) in particular, conventional technology allows for a display device using light-emitting diodes in a configuration of blue, green, and red light-emitting diodes arranged on a substrate.

Improving the luminous efficiency of the light-emitting diodes is important in consideration of reducing electric power consumption and the like. Technology for improving the luminous efficiency by using a resonator structure for the light-emitting diode has been proposed (e.g., Patent Literature 1). Patent Literature 1 describes a bottom electrode (i.e., a mirror), a transparent conducting layer, a hole transport layer, a light-emitting layer, a electron transport layer, and a top electrode (i.e., a half-mirror), layered to form a light-emitting diode, in which the optical distance between the mirror and the half-mirror are adjusted so as to maximize the luminous efficiency for a blue, green, or red light-emitting diode (see paragraph 0012).

Also, achieving superb color reproducibility in the display device is important, in addition to improving luminous efficiency. Improvements to the color purity of each light-emitting diode are necessary in order to improve color reproducibility. Providing a color filter (hereinafter, CF) for each light-emitting diode blocks unwanted wavelength components. This has been proposed as an approach to improving the color purity of emitted light.

### CITATION LIST

### Patent Literature

### [Patent Literature 1]

Japanese Patent Application Publication No. 2005-116516

### SUMMARY

However, the inventors have experimentally discovered that combining a maximum layer thickness obtained through a simple resonator structure with a color filter presents difficulties in achieving improvements to luminous efficiency as well as to color purity.

One non-limiting and exemplary embodiment provides a light-emitting diode having high color purity as well as high luminous efficiency, and a display device capable of realizing excellent color reproducibility using the light-emitting diode.

In one general aspect, the techniques disclosed here feature a light-emitting diode comprising a light-emitting layer between a reflective electrode and a transparent electrode, the light-emitting layer emitting blue light, wherein a functional layer is interposed between the reflective electrode and the light-emitting layer, and the functional layer has an optical thickness of no less than 455.4 nm and no more than 475.8 nm.

With the above structure, the light-emitting diode is able to achieve improvements to luminous efficiency and obtain high color purity.

These general and specific aspects may be implemented using a manufacturing method.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

FIG. 1 is a cross-sectional diagram schematically representing a portion of an organic EL display pertaining to an Embodiment.

FIG. 2 is a table indicating the target color in terms of color purity standards (i.e., the EBU standards) for a display.

FIG. 3 is a table indicating the thickness and the optical constants for each layer.

FIG. 4 illustrates the relationship between PL spectral intensity and wavelength for each light-emitting material.

FIG. 5 illustrates the change in luminous efficiency and x color component with respect to change in transparent conductive layer 4 thickness for a green light-emitting diode.

FIG. 6 is a table indicating the relationship between optical layer thickness, luminous efficiency, x color component, and value m for the green light-emitting diode.

FIG. 7 illustrates the change in luminous efficiency and y color component with respect to change in transparent conductive layer 4 thickness for a red light-emitting diode.

FIG. 8 is a table indicating the relationship between optical layer thickness, luminous efficiency, y color component, and value m for the red light-emitting diode.

FIG. 9 illustrates the change in luminous efficiency and y color component with respect to change in transparent conductive layer 4 thickness for a blue light-emitting diode.

FIG. 10 is a table indicating the optical layer thickness, luminous efficiency, y color component, and value m for the blue light-emitting diode under a color-focused setting.

FIG. 11 is a table listing optimal conditions for a efficiency-focused setting and for two color-focused settings of the blue light-emitting diode.

FIG. 12 is a table indicating the optical layer thickness, luminous efficiency, y color component, and value m for the blue light-emitting diode under the color-focused setting.

FIG. 13 is a perspective view diagram of a display device pertaining to a variation.

### DETAILED DESCRIPTION

### 1. Embodiment

In one aspect, the light-emitting diode pertaining to the present Embodiment features a light-emitting diode comprising a light-emitting layer between a reflective electrode and a transparent electrode, the light-emitting layer emitting blue light, wherein a functional layer is interposed between the reflective electrode and the light-emitting layer, and the functional layer has an optical thickness of no less than 455.4 nm and no more than 475.8 nm.

According to this definition, luminous efficiency is improved while high color purity is realized.

In another aspect, a light-emitting diode comprises a light-emitting layer between a reflective electrode and a transparent electrode, the light-emitting layer emitting blue light, wherein at least one functional layer is interposed between the reflective electrode and the light-emitting layer, and the functional layer has an optical thickness of L, in nm, that satisfies:

$$\begin{matrix}[ Math . 1 ] & \\ \frac{2 L}{λ} + \frac{Φ}{2 π} = m & \end{matrix}$$

where λ is a wavelength of 455 nm, Φ is a phase shift of the reflective electrode, and m is a value satisfying a relation 2.5≦m<3.

According to this configuration, the light-emitting diode emitting blue light satisfies the color purity requirements of the display, and also achieves improvements in luminous efficiency.

In a further aspect, a display device comprising an array of light-emitting diodes, the light-emitting diodes each emitting one of blue light, green light, and red light, wherein the light-emitting diode described above is the light-emitting diode emitting the blue light.

According to this configuration, the color purity of blue light is improved, enabling improvements to the color reproducibility of the pixels, and enables reduction in the electric power consumption of the display device through improvements in luminous efficiency.

In an additional aspect, the light emitting elements emitting one of the green light and the red light each comprise a light-emitting layer between a reflective electrode and a transparent electrode, the light-emitting layer emitting the one of the green light and the red light, a functional layer is interposed between the reflective electrode and the light-emitting layer, and the functional layer has an optical thickness of L, in nm, that satisfies:

$$\begin{matrix}[ Math . 2 ] & \\ \frac{2 L}{λ} + \frac{Φ}{2 π} - m & \end{matrix}$$

where λ is a wavelength of 510 nm for the green light and 640 nm for the red light, Φ is a phase shift of the reflective electrode, and m is an integer.

Also, m has a value of two.

According to this configuration, the luminous efficiency and color purity of green light and red light are improved, thus enabling reductions in the electric power consumption of the display device and improvements to the color reproducibility of the pixels.

### 2. Embodiment

The following describes an Embodiment of the present disclosure, with reference to the accompanying drawings.

### 2.1. Organic Electroluminescence Display Configuration

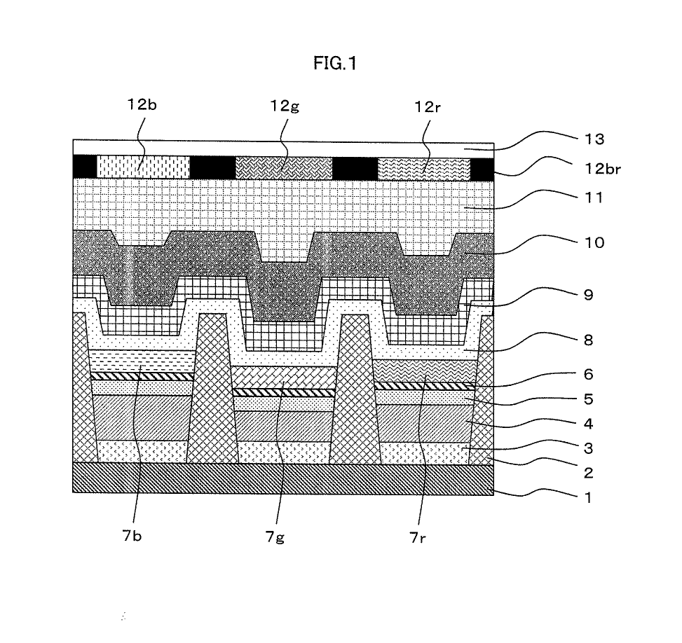

FIG. 1 is a cross-sectional diagram schematically representing a portion of an organic EL display pertaining to the Embodiment.

The organic EL display pertaining to the present Embodiment is made up of top emission organic EL cells each serving as a light-emitting diode, arranged on a substrate 1 in a matrix arrangement. Each light-emitting diode includes a light-emitting layer 7 emitting one of red light (R), green light(G), and blue light (B). In the following description, the light-emitting layer 7 is referenced according to the colour emitted thereby, as light-emitting layer 7b for blue light, light-emitting layer 7g for green light, and light-emitting layer 7r for red light. Each light-emitting diode is defined by a bank 2, which is configured as a pixel bank (i.e., a lattice bank).

Each light-emitting diode includes a reflective electrode 3, five functional layers (i.e., a transparent conductive layer 4, a hole injection layer 5, a hole transport layer 6, the light-emitting layer 7, and an electron transport layer 8), and a transparent electrode 9, layered in the stated order. As shown in FIG. 1, the electron transport layer 8 and the transparent electrode 9 are not divided between light-emitting diodes by the bank 2.

The light-emitting diodes have a resonator structure imparted by the reflective electrode 3. The emitted light passing through the transparent electrode 9 includes a component of light radiating toward the transparent electrode 9 from the light-emitting layers 7b, 7g, and 7r (hereinafter, direct light), and a component of light radiating toward the reflective electrode 3 from the light-emitting layers 7b, 7g, and 7r and then reflected by the reflective electrode 3 (hereinafter, reflected light). The distance separating the light-emitting layers 7b, 7g, and 7r from the reflective electrode 3 is adjusted to strengthen the interference between the direct light and the reflected light, enabling greater luminous efficiency to be achieved in the light-emitting diode. The separation is adjusted by adjusting the thickness of the functional layers (i.e., the transparent conductive layer 4, the hole injection layer 5, and the hole transport layer 6) between the light-emitting layers 7b, 7g, and 7r and the reflective electrode 3.

A thin-film sealing layer 10, a resin sealing layer 11, a color filter 12 serving as a color correction layer, and a glass layer 13, are layered over the light-emitting diode in the stated order. The color filter provided over each light-emitting diode is hereinafter referred according to the color thereof, as color filter 12b for blue, color filter 12g for green, and color filter 12g for red. The materials used in each of the layers are described below.

### 2.2. Layer Thickness Adjustment for Color and Efficiency

The thickness of the layers pertaining to the aforementioned distance adjustment is decided under certain considerations of color and luminous efficiency.

The settings made in consideration of color are hereinafter termed color-focused settings, and those made in consideration of luminous efficiency are hereinafter termed efficiency-focused settings.

The color considerations are for the color required by broadcast standards, such as the EBU standards.

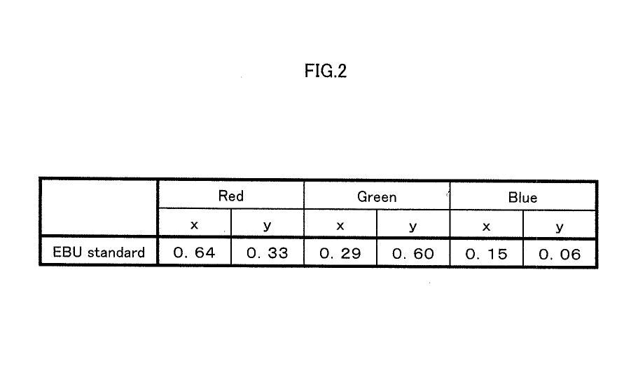

FIG. 2 indicates the colors (target colors) defined by the EBU standard used for the present Embodiment.

The (x, y) coordinates of each color are given in the CIE color space. As shown in FIG. 2, the target color for red is (0.64, 0.33), the target color for green is (0.29, 0.60), and the target color for blue is (0.15, 0.06). The color-focused setting is a method of setting the distance between the light-emitting layer and the reflective electrode such that the color of the emitted light approaches the target color.

In consideration of electric power consumption and the like, high luminous efficiency is generally considered to be beneficial. The efficiency-focused setting involves first adjusting the distance between the light-emitting layer and the reflective electrode so as to maximize the luminous efficiency, and then setting the color filter (hereinafter, CF) characteristics (e.g., the transmission spectrum) so as to achieve the target color with the color of the emitted light. The color filter is generally used for color correction. For the color-focused setting, there may be no need to use the color filter in order to approximate the target color. Alternatively, a high-transmission color filter may be used for relatively weak color correction, compared to the efficiency-focused setting.

Conventionally, the layer thickness has been set according to the belief that loss in the luminous efficiency of the light-emitting diode is ultimately less for an efficiency-focused setting where the luminous efficiency is greater before color correction, compared to a color-focused setting where the luminous efficiency before color correction is lower. However, while this applies to red light-emitting diodes and to green light-emitting diodes, the inventors experimentally discovered that the conventional approach does not apply to blue light-emitting diodes.

Specifically, the luminous efficiency was greatly diminished due to color correction with a color filter that greatly differs from the target color when the efficiency-focused setting was used for a blue light-emitting diode, in comparison to the color-focused setting. Also, although the efficiency-focused setting ordinarily produces higher luminous efficiency as the distance between the light-emitting layer and the reflective electrode decreases, experiments made it clear that for the blue light-emitting diodes, efficiency was improved by having the distance between the light-emitting layer and the reflective electrode be greater than the wavelength of red light.

### 2.3. Experiments and Layer Thickness Adjustments

In terms of color, the layer thickness is set such that the green light-emitting diode has an x color component of 0.29 or less, the red light-emitting diode has a y color component of 0.33 or less, and the blue light-emitting diode has a y color component of 0.06 or less.

The luminous efficiency is set within 80% of the peak value. This range of 80% of the peak value is set to reflect an assumption of 20% manufacturing error in the display plane.

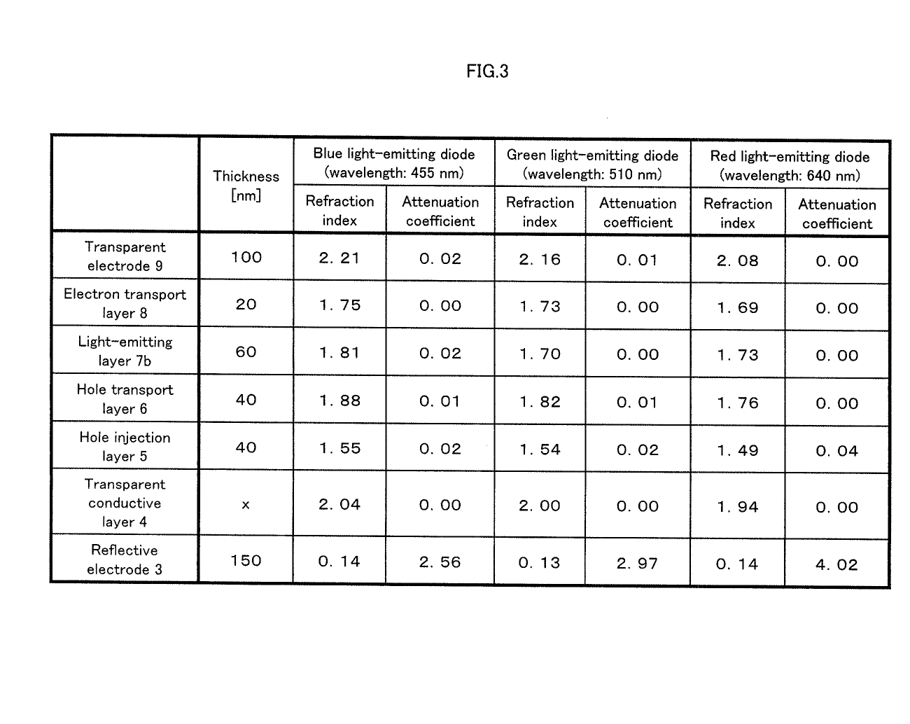

FIG. 3 shows a table listing the dimensions d and the optical constants (i.e., the refraction index n and the attenuation coefficient k) of the materials used for each layer of the blue, green, and red light-emitting diodes used for the experiments.

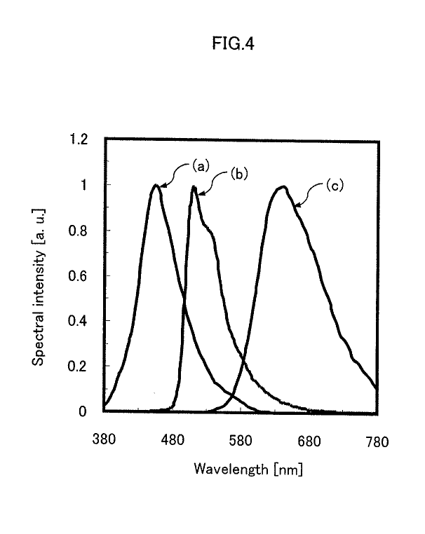

The optical constants are given for respective wavelengths of 455 nm for the blue light-emitting diode, 510 nm for the green light-emitting diode, and 640 nm for the light-emitting diode. The material used in the transparent conductive layer 4 is indium-tin oxide (hereinafter, ITO). The respective materials for the light-emitting layers 7b, 7g, and 7r are spiroanthracene prepared by Covion Organic Semiconductors GmbH, Ir(PPy)3, and RP 158 prepared by SUMATION Co. Ltd. FIG. 4 illustrates the relationship between spectral intensity and wavelength for each light-emitting material. In the graph of FIG. 4, line (a) indicates the blue light-emitting material, line (b) indicates the green light-emitting material, and line (c) indicates the red light-emitting material.

The layer thickness is fixed and common to the blue, green, and red light-emitting diodes, with the exception of the transparent conductive layer 4. The distance between the light-emitting layer and reflective electrode is adjusted by changing the thickness of the transparent conductive layer 4. The optical layer thickness is calculated as the product of the thickness and the refraction index.

### 2.3.1. Green Light-emitting diode

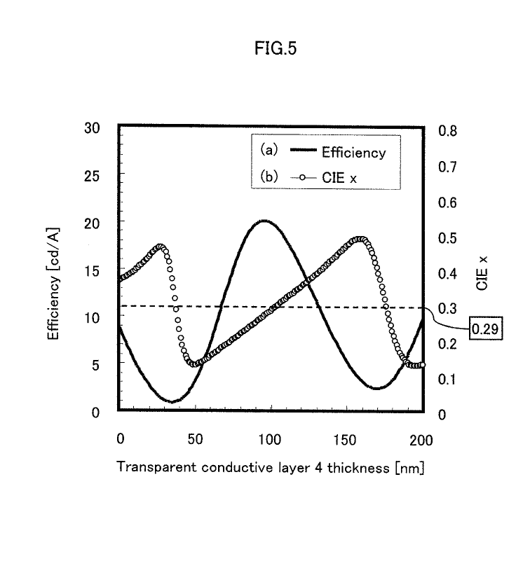

FIG. 5 indicates the change in the luminous efficiency and the x color component of the green light-emitting diode with respect to the change in transparent conductive layer 4 thickness.

In FIG. 5, solid line (a) indicates the change in luminous efficiency (axis label: efficiency) with respect to the change in transparent conductive layer 4 thickness. The plotted circles forming line (b) indicate the change in the x color component (axis label: CIE x) with respect to the change in transparent conductive layer 4 thickness.

For the green light-emitting diode, the luminous efficiency (see line (a)) peaks when the thickness is near 96 nm, while the color (see line (b)) is near the target color (x=0.29). Accordingly, when the target color is approximated (i.e., when the color purity of the emitted light is enhanced), weaker spectrum correction is sufficient. Thus, a color filter with high transparency is usable. Thus, the efficiency-focused setting is applicable to the green light-emitting diode.

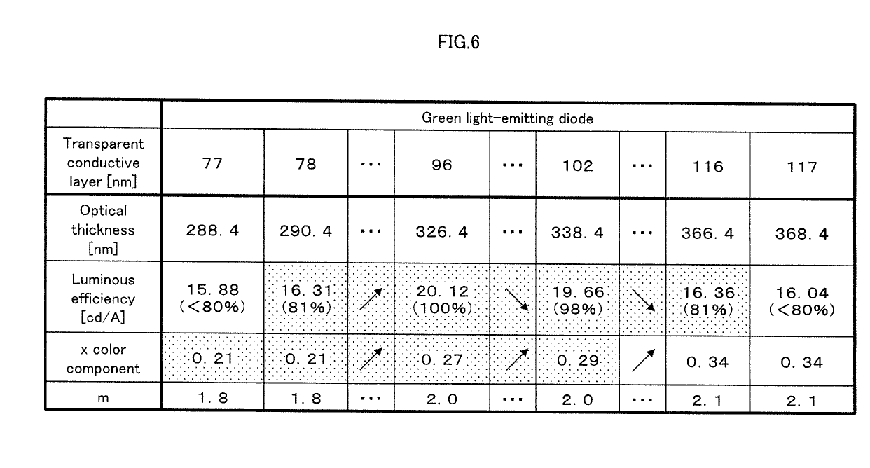

FIG. 6 indicates the optical layer thickness, the luminous efficiency, the x color component, and a value m with respect to the change in transparent conductive layer 4 thickness for the green light-emitting diode.

FIG. 6 is a table focused on the boundary conditions revealed in the graph from FIG. 5, describing the luminous efficiency and the value m. The value m is given as follows.

$$\begin{matrix}[ Math . 3 ] & \\ \frac{2 L}{λ} + \frac{Φ}{2 π} = m & ( Equation 1 )\end{matrix}$$

Thus, the value is derived.

Equation 1 represents the relationship between the total optical layer thickness L (in nm) of the transparent conductive layer 4, the hole injection layer 5, and the hole transport layer 6, the resonant wavelength λ (in nm), and the phase shift Φ (in radians) of the resonator structure.

The phase shift Φ for the reflective electrode 3 is as given by Equation 2, below.

$$\begin{matrix}[ Math . 4 ] & \\ Φ = π - {tan}^{- 1} ( \frac{2 {n}_{1} {k}_{0}}{{n}_{1}^{2} - ( {n}_{0}^{2} + {k}_{o}^{2} )} ) & ( Equation 2 )\end{matrix}$$

Here, n₁ is the refraction index of the transparent conductive layer 4, n₀ is the refraction index of the reflective electrode 3, and k₀ is the attenuation coefficient of the reflective electrode 3. Also, Φ/2π=0.7. FIG. 6 indicates that the luminous efficiency of the green light-emitting diode is within 80% of the peak value, and that the x color component is 0.29 or less when the thickness of the transparent conductive layer 4 ranges from 78 nm to 102 nm, inclusive. The luminous efficiency is maximal (i.e., 20.12 cd/A) when the thickness of the transparent conductive layer 4 is 96 nm. Here, the optical layer thickness L is 326.4 nm and the value m computed from Equation 1 is 2.0.

### 2.3.2. Red Light-Emitting Diode

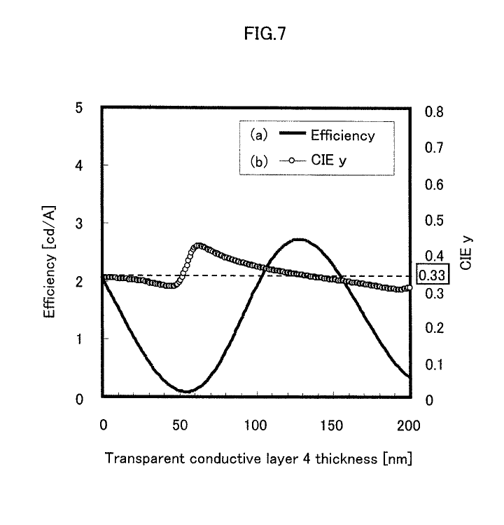

FIG. 7 indicates the change in the luminous efficiency and the y color component of the red light-emitting diode with respect to the change in transparent conductive layer 4 thickness.

In FIG. 7, solid line (a) indicates the change in luminous efficiency (axis label: efficiency) with respect to the change in transparent conductive layer 4 thickness. The plotted circles forming line (b) indicate the change in the y color component with respect to the change in transparent conductive layer 4 thickness.

For the red light-emitting diode, the luminous efficiency (see line (a)) peaks when the thickness is near 141 nm, while the color (see line (b)) is near the target color (y=0.33). Accordingly, when the target color is approximated, weaker spectrum correction is sufficient. Thus, a color filter with high transparency is usable. Thus, the efficiency-focused setting is applicable to the red light-emitting diode.

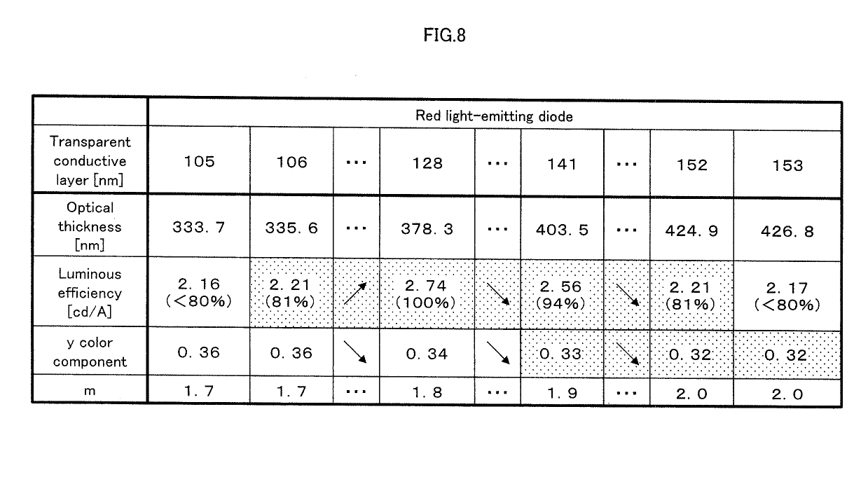

FIG. 8 indicates the optical layer thickness, the luminous efficiency, the y color component, and the value m with respect to the change in transparent conductive layer 4 thickness for the red light-emitting diode.

FIG. 8 is a table focused on the boundary conditions revealed in the graph from FIG. 7, describing the luminous efficiency and the value m. The value m is derived from Equation 1.

FIG. 8 indicates that the luminous efficiency of the red light-emitting diode is within 80% of the peak value, and that the y color component is 0.33 or less when the thickness of the transparent conductive layer 4 ranges from 141 nm to 152 nm, inclusive. The luminous efficiency is highest when the thickness of the transparent conductive layer 4 is 141 nm. Here, the optical layer thickness L is 403.5 nm and the value m computed from Equation 1 is 1.9 (approximately 2). Here, the luminous efficiency is 2.56 cd/A for the red light-emitting diode.

### 2.3.3. Blue Light-Emitting Diode

### (1) Setting Method Selection

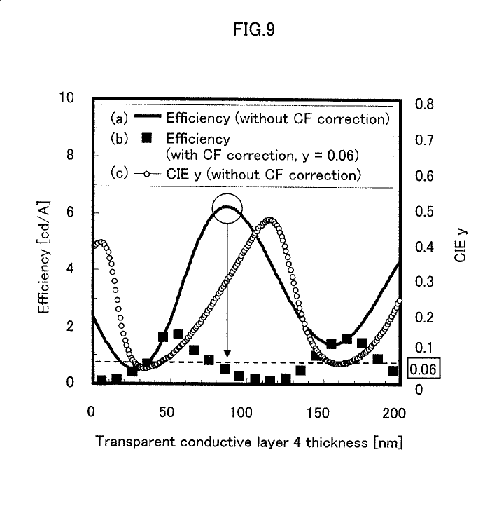

FIG. 9 indicates the change in the luminous efficiency and in the y color component of the blue light-emitting diode with respect to the change in transparent conductive layer 4 thickness.

In FIG. 9, solid line (a) indicates the change in luminous efficiency with respect to the change in transparent conductive layer 4 thickness, without CF correction. The plotted circles forming line (c) indicate the change in the y color component with respect to the change in transparent conductive layer 4 thickness, without CF correction. Also, the plotted squares forming line (b) indicate the change in luminous efficiency with respect to the change in transparent conductive layer 4 thickness, when CF correction is performed to obtain a target color where y=0.06.

When the efficiency-focused setting is used, the thickness of the transparent conductive layer 4 is 87 nm, which is the peak luminous efficiency according to line (a) of FIG. 9. The color (see line (c)) obtained under these conditions is quite different from the target color (0.06). Thus, CF correction is used to obtain the target color. However, the CF correction that should approximate the target color (see line (b)) produces a luminous efficiency that is reduced to 0.39 cd/A. This is because, although strong spectrum correction is necessary in order to approach the target color, the color filter producing such strong spectrum correction has a low transmission ratio. Specifically, the CF transmission ratio is 6.3%.

When the color-focused setting is used, the thickness indicated by line (b) of FIG. 9 for a thickness of 0.06 or less is employed. When the color indicated by line (b) is 0.06 or less, and the thickness indicated at the peak of line (a) is 44 nm (when the luminous efficiency is 1.44 cd/A) and 166 nm (when the luminous efficiency is 1.62 cd/A), then the luminous efficiency is greater when the efficiency-focused setting is used, for either of the aforementioned luminous efficiency values. Thus, the efficiency-focused setting is applicable to the blue light-emitting diode.

### (2) Color-Focused Setting

As described above, the blue light-emitting diode is set such that the luminous efficiency has a peak value within 80%, and such that the y color component is 0.06 or less (hereinafter termed blue layer thickness conditions). As explained with reference to FIG. 9, the layer thickness satisfying these conditions for the color-focused setting is set according to the relative thickness of the transparent conductive layer in comparison to the red light-emitting diode, with one setting for a thinner case (hereinafter, color-focused setting 1), and another setting for a thicker case (hereinafter, color-focused setting 2).

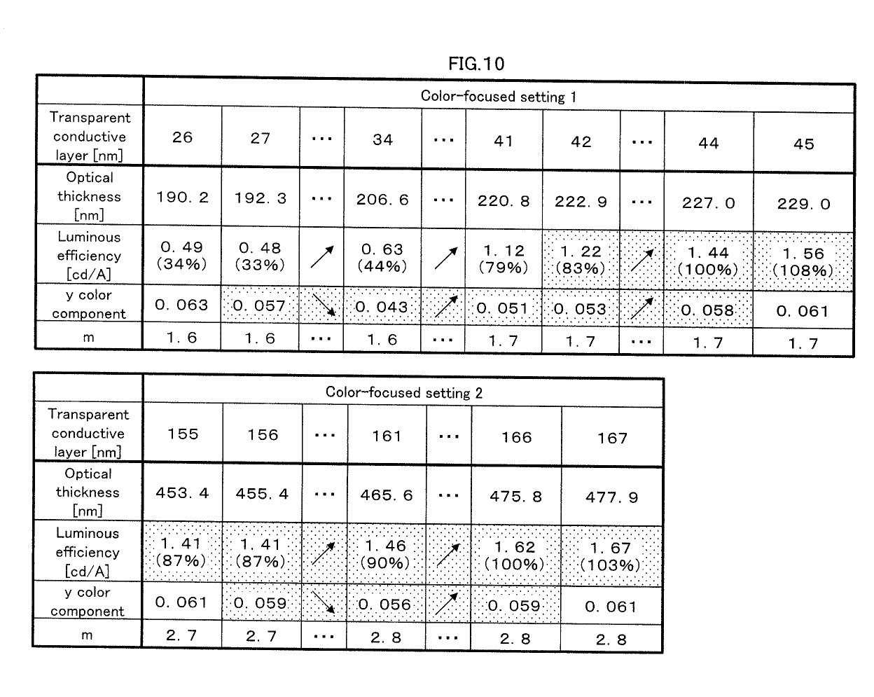

FIG. 10 presents a pair of tables respectively giving the optical layer thickness, the luminous efficiency, the y color component, and the value m with respect to varying thickness of the transparent conductive layer 4 for the blue light-emitting diode, for color-focused setting 1 and for color-focused setting 2.

FIG. 10 gives tables focused on the boundary conditions revealed in the graph from FIG. 9, describing the luminous efficiency and the value m. The value m is derived from Equation 1.

As shown in FIG. 10, for color-focused setting 1, the blue layer thickness conditions are satisfied when the thickness of the transparent conductive layer 4 is between 42 nm and 44 nm, inclusive. Also, for color-focused setting 2, the blue layer thickness conditions are satisfied when the thickness of the transparent conductive layer 4 is between 156 nm and 166 nm, inclusive. Here, the value m is beneficially such that the relation 2.5≦m<3 is satisfied.

### (3) Comparison of Efficiency-Focused Setting and Color-Focused Setting

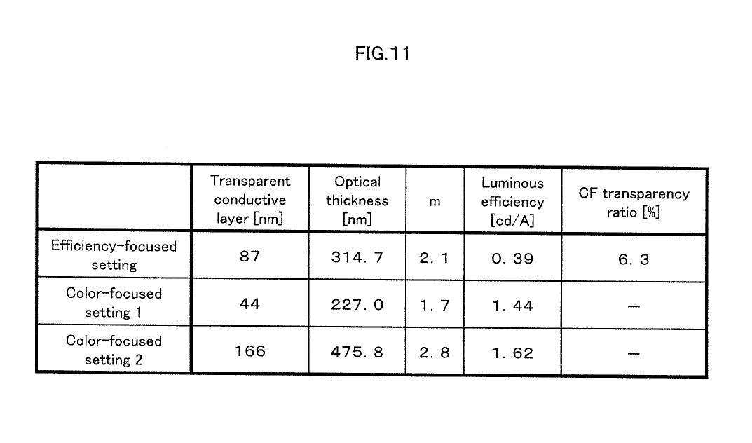

FIG. 11 indicates the thickness of the transparent conductive layer 4 under the best conditions for the efficiency-focused setting, color-focused setting 1, and color-focused setting 2, as well as the optical layer thickness L and the value m used in Equation 1, and the luminous efficiency and the color filter transparency ratio serving as device properties

For the efficiency-focused setting, the luminous efficiency is highest when the thickness of the transparent conductive layer 4 is 87 nm. Here, the optical layer thickness L is 314.7 nm and the value m is 2.1 (approximately 2).

However, for color-focused setting 1 when the thickness of the transparent conductive layer 4 is 44 nm and the color is 0.06 or less, the luminous efficiency peaks at 1.44 cd/A (where the color is 0.058). Here, the optical layer thickness L is 227.0 nm and the value m is 1.7.

Also, for color-focused setting 2 when the thickness of the transparent conductive layer 4 is 166 nm and the color is 0.06 or less, the luminous efficiency peaks at 1.62 cd/A (where the color is 0.059). Here, the optical layer thickness L is 475.8 nm and the value m computed from Equation 1 is 2.8.

The luminous efficiency is thus 0.39 cd/A for the efficiency-focused setting and 1.44 cd/A for color-focused setting 1, representing a 3.7-fold increase over the efficiency-focused setting. Thus, color-focused setting 1 achieves greater luminous efficiency than an efficiency-focused setting.

Also, the luminous efficiency is 1.62 cd/A for color-focused setting 2, representing a further 10% increase in luminous efficiency over color-focused setting 1.

### (4) Thickness Variation for Hole Injection Layer and Hole Transport Layer

In the above-described Embodiment, the thickness of the transparent conductive layer 4 is varied. However, the important parameter manipulated in the color-focused setting is not the thickness of the transparent conductive layer 4 but rather the optical layer thickness L of the transparent conductive layer 4, the hole injection layer 5, and the hole transport layer 6, in combination. Interference between the direct light and the reflected light is a likely result of increasing the luminous efficiency of the light-emitting diode.

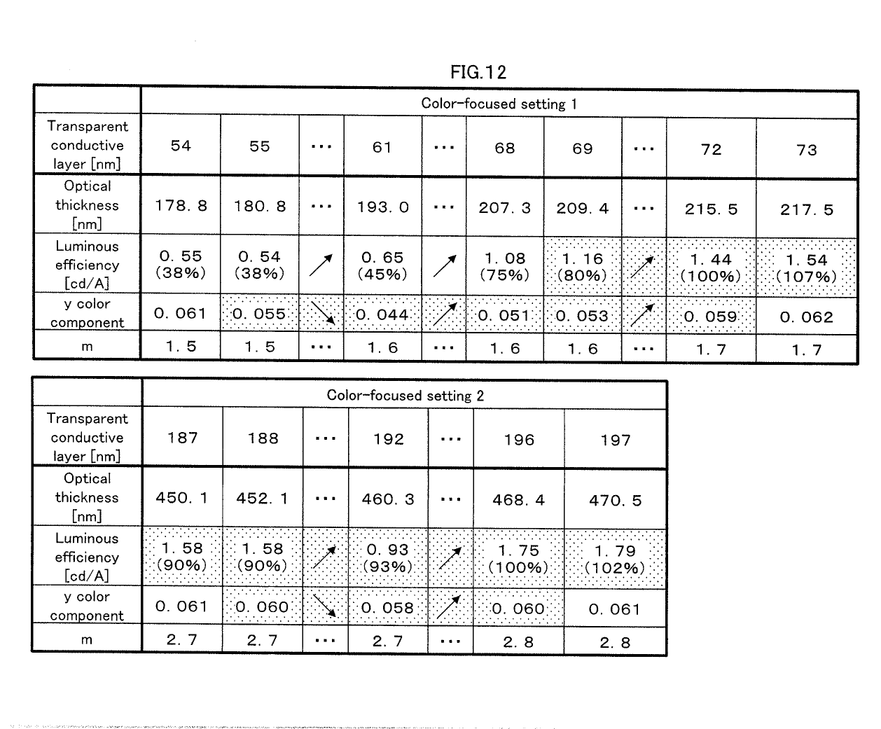

FIG. 12 indicates the optical layer thickness, the luminous efficiency, the y color component, and the value m with respect to the change in transparent conductive layer 4 thickness in a situation where the thickness of the hole injection layer and of the hole transport layer for the blue light-emitting diode is 20 nm.

For color-focused setting 1, the blue layer thickness conditions are satisfied when the thickness of the transparent conductive layer 4 is between 69 nm and 72 nm, inclusive. The luminous efficiency peaks (at 1.44 cd/A) when the thickness of the transparent conductive layer 4 is 72 nm. Here, the optical layer thickness L is 215.5 nm and the value m computed from Equation 1 is 1.7.

For color-focused setting 2, the blue layer thickness conditions are satisfied when the thickness of the transparent conductive layer 4 is between 188 nm and 196 nm, inclusive. The luminous efficiency peaks (at 1.75 cd/A) when the thickness of the transparent conductive layer 4 is 196 nm. Here, the optical layer thickness L is 468.4 nm and the value m computed from Equation 1 is 2.8.

Comparing the luminous efficiency of the color-focused settings 1 and 2 reveals that color-focused setting 2 provides a 20% improvement in luminous efficiency over color-focused setting 1.

### 3. Materials

The substrate 1 is, for a thin film transistor (hereinafter, TFT) substrate. The material for the substrate 1 is, for example, an insulating material such as a non-alkali glass, a soda glass, a non-fluorescent glass, a phosphoric glass, a boric gas, quartz, an acrylic resin, a styrene resin, a polycarbonate resin, an epoxy resin, a polyethylene resin, a polyester resin, a silicone resin, aluminium oxide, and so on.

The bank 2 is made of a resin or a similar organic material having insulating properties. For example, the organic material may be an acrylic resin, a polyimide resin, a novolac-type phenol resin, or the like. The bank 2 is also beneficially resistant to organic solvents. Further, processes such as etching and baking are applied to the bank 2. Consequently, a material with high resistance to deformation and transformation under these processes is desirable.

The reflective electrode 3 is electrically connected to the TFT disposed as the substrate 1, functions as a cathode for the light-emitting diodes, and reflects light emitted by the light-emitting layers 7b, 7g, and 7r. The reflective function may be achieved by the component material of the reflective electrode, or by a reflective coating applied to a surface portion of the reflective electrode 3. The reflective electrode 3 is formed of silver, aluminium, or similar. Alternatively, the reflective electrode 3 material may be an alloy such as APC (an alloy of silver, palladium, and copper), MoCr (an alloy of molybdenum and chromium), NiCr (an alloy of nickel and chromium), or the like. A material having high optical reflectivity is beneficial for a top-emission light-emitting diode.

The transparent conductive layer 4 is interposed between the reflective electrode 3 and the hole injection layer 5, provides an excellent junction between the reflective electrode 3 and the hole injection layer 5, and serves as a protective layer preventing natural oxidation of the reflective electrode 3 from occurring during manufacture, immediately after formation. The material for the transparent conductive layer 4 is a conductive material that beneficially has sufficient transparency to pass the light emitted by the light-emitting layers 7b, 7g, and 7r, such as ITO or indium zinc oxide (hereinafter, IZO). These materials are favored because good transmission properties are maintained despite formation occurring at room temperature.

The hole injection layer 5 injects holes into the light-emitting layers 7b, 7g, and 7r. The hole injection layer 5 material is, for example, WOₓ(tungsten oxide), MoOₓ (molybdenum oxide), MoₓW_{y}O_{z} (molybdenum-tungsten oxide), or similar. The hole injection layer 5 is beneficially formed from a metal compound injecting holes into the light-emitting layer. Such metal compounds include metal oxides, metal nitrides, and metal oxide nitrides.

Holes are easily injected when the hole injection layer 5 is made from a particular metal compound, which provides superb light-emitting characteristics by effectively supplying electrons to the light-emitting layers 7b, 7g, and 7r. The particular metal compound is beneficially a transition metal. Transition metals have a plurality of possible oxidation numbers and thus have a plurality of energy levels. As a result, hole insertion is simplified and the drive voltage is reduced.

The hole transport layer 6 transports holes to the light-emitting layers 7b, 7g, and 7r. Examples of the material for the hole transport layer 6 include a triazole derivative, an oxadiazole derivative, an imidazole derivative, a polyarylalkane derivative, a pyrazoline derivative and pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a porphyrin compound, an aromatic tertiary amine compound and styrylamine compound, a butadiene compound, a polystyrene derivative, a hydrazone derivative, a triphenylmethane derivative, or a tetraphenylbenzene derivative. In particular, a polyphyrin compound, an aromatic tertiary amine compound, and a styrylamine compound are beneficial.

The light-emitting layers 7b, 7g, and 7r respectively emit light that is blue, green, and red. The light-emitting layers 7b, 7g, and 7r are preferably formed from a fluorescent material such as such as an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, metal complex of an 8-hydroxyquinoline compound, metal complex of a 2-bipyridine compound, complex of a Schiff base and a group three metal, metal complex of oxine, rare earth metal complex, and so on.

The electron transport layer 8 transports the electrons inserted from the transparent electrode 9 to the light-emitting layers 7b, 7g, and 7r. The electron transport layer 8 is, for example, formed from one of a nitro-substituted fluorenone derivative, a thiopyran dioxide derivative, a diphenylquinone derivative, a perylene tetracarboxyl derivative, an anthraquinodimethane derivative, a fluoronylidene methane derivative, an anthrone derivative, an oxadiazole derivative, a perinone derivative, and a quinolone complex derivative.

The transparent electrode 9 is formed from, for example, ITO, IZO, or the like. A material having high optical transparency is beneficial for a top-emission light-emitting diode.

The thin-film sealing layer 10 protects the layers sandwiched between it and the substrate 1 from exposure to moisture and to the atmosphere. The thin-film sealing layer 10 material is silicon mononitride, silicon oxynitride, or similar.

The resin sealing layer 11 joins a back panel, composed of the layers from the substrate 1 through the thin-film sealing layer 10, to a front panel composed of the color filters 12b, 12g, and 12r, and serves to protect the layers from exposure to moisture and to the atmosphere. The resin sealing layer 11 material is, for example, a resin adhesive or similar. A material having high optical transparency is beneficial for a top-emission light-emitting diode.

### 4. Summary

As described above, the blue light-emitting diode emits light in a color greatly deviates from the target color when the efficiency-focused setting is used, and efficiency is then decreased by the color filter used for color correction. However, when the color-focused setting is used with, as discussed, a thickness of 156 nm to 166 nm, inclusive, for the transparent conductive layer 4, the color purity of the emitted color more closely approaches the target color needed by the display, thus improving luminous efficiency. This result is plausibly produced by interference between the direct light and the reflected light. In such circumstances, the important factor is not that thickness of the transparent conductive layer 4 is of 156 nm to 166 nm, inclusive, but is rather the total optical layer thickness L of the transparent conductive layer 4, the hole injection layer 5, and the hole transport layer 6. Accordingly, for the blue light-emitting diode, the total optical layer thickness L of the transparent conductive layer 4, the hole injection layer 5, and the hole transport layer 6 should fall within a range of 455.4 nm to 475.8 nm, as equivalent efficiency is achieved by satisfying this condition.

As for the green light-emitting diode, the thickness of the transparent conductive layer 4 is beneficially 96 nm, and the total optical layer thickness L of the transparent conductive layer 4, the hole injection layer 5, and the hole transport layer 6 is beneficially 326.4 nm. This result of equivalent efficiency is achieved by satisfying the condition such that the total optical layer thickness L of the transparent conductive layer 4, the hole injection layer 5, and the hole transport layer 6 should fall within a range of 290.4 nm to 338.4 nm.

Also, for the red light-emitting diode, the thickness of the transparent conductive layer 4 is beneficially 149 nm, and the total optical layer thickness L of the transparent conductive layer 4, the hole injection layer 5, and the hole transport layer 6 is beneficially 419.3 nm. This result of equivalent efficiency is achieved by satisfying the condition such that the total optical layer thickness L of the transparent conductive layer 4, the hole injection layer 5, and the hole transport layer 6 should fall within a range of 403.5 nm to 424.9 nm.

A display provided with such light-emitting diodes realizes greater luminous efficiency for each color, as well as greater color purity in the emitted colors, reduced electric power consumption, and higher color reproducibility.

### 5. Variations

Although the present disclosure is described above in terms of the above-described Embodiment, no limitation is intended. Several variations are also plausible, provided that the scope of the disclosure is not exceeded thereby.

For example, the organic EL display pertaining to the Embodiment may be mounted in a display device 100.

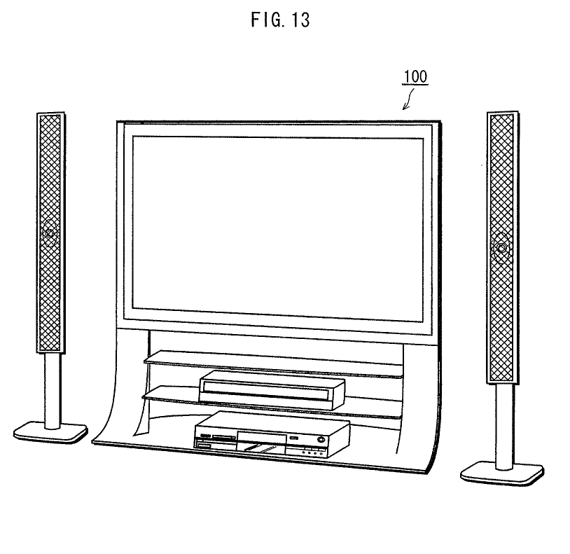

FIG. 13 is a schematic perspective view diagram of the display device 100.

Accordingly, the results described above area also achievable for the organic EL display device.

Also, the above-described Embodiment described functional layers in a three-layer structure (transparent electrode, hole transport layer, hole injection layer). However, no limitation is intended. A two-layer structure or a single-layer structure is also possible.

### INDUSTRIAL APPLICABILITY

The light-emitting diode of the present disclosure is applicable to display device requiring low electric power consumption and high color reproducibility, and is particularly applicable to various types of light sources.

### REFERENCE SIGNS LIST

1 Substrate
2 Bank
3 Reflective electrode
4 Transparent conductive layer
5 Hole injection layer
6 Hole transport layer
7b, 7g, 7r Light-emitting layers
8 Electron transport layer
9 Transparent electrode
10 Thin-film sealing layer
11 Resin sealing layer
12b, 12g, 12r Color filters
13 Glass layer

1. A light-emitting diode comprising a light-emitting layer between a reflective electrode and a transparent electrode, the light-emitting layer emitting blue light, wherein
a functional layer is interposed between the reflective electrode and the light-emitting layer, and
the functional layer has an optical thickness of no less than 455.4 nm and no more than 475.8 nm.

2. A light-emitting diode comprising a light-emitting layer between a reflective electrode and a transparent electrode, the light-emitting layer emitting blue light, wherein
at least one functional layer is interposed between the reflective electrode and the light-emitting layer, and
the functional layer has an optical thickness of L, in run, that satisfies:
$$\begin{matrix}[ Math . 1 ] & \\ \frac{2 L}{λ} + \frac{Φ}{2 π} = m & \end{matrix}$$
where λ is a wavelength of 455 nm, Φ is a phase shift of the reflective electrode, and in is a value satisfying a relation 2.5≦m<3.

3. A display device comprising an array of light-emitting diodes, the light-emitting diodes each emitting one of blue light, green light, and red light, wherein
the light-emitting diode emitting the blue light is the light-emitting diode of claim 1.

4. The display device of claim 3, wherein
the light emitting elements emitting one of the green light and the red light each comprise a light-emitting layer between a reflective electrode and a transparent electrode, the light-emitting layer emitting the one of the green light and the red light,
a functional layer is interposed between the reflective electrode and the light-emitting layer, and
the functional layer has an optical thickness of L, in nm, that satisfies:
$$\begin{matrix}[ Math . 2 ] \\ \frac{2 L}{λ} + \frac{Φ}{2 π} = m\end{matrix}$$
where λ, is a wavelength of 510 nm for the green light and 640 nm for the red light, Φ is a phase shift of the reflective electrode, and m is an integer.

5. The display device of claim 4, wherein
m has a value of two.

6. The display device of claim 3, further comprising a color filter opposite the transparent electrode.
